(19) United States
(12) Patent Application Publication
(10) Pub. No.: US 2004/0071878 A1
(43) Pub. Date: Apr. 15, 2004

(54) Surface preparation using plasma for ALD Films

(75) Inventors: Jorg Schuhmacher, Grez-Doiceau (BE); Ana Martin Hoyas, Leuven (BE); Marc Schaekers, Leuven (BE); Serge Vanhaelemeersch, Leuven (BE)

Correspondence Address: MCDONNELL BOEHNEN HULBERT & BERGHOFF, 300 SOUTH WACKER DRIVE, SUITE 3200, CHICAGO, IL, 60606, US

(73) Assignee: Interuniversitair Microelektronica Centrum (IMEC VZW), Leuven (BE)

(21) Appl. No.: 10/641,954

(22) Filed: Aug. 15, 2003

Related U.S. Application Data
(60) Provisional application No. 60/404,037, filed on Aug. 15, 2002.

(51) Int. Cl. C23C 16/00; B32B 9/04

(52) U.S. Cl. 427/255.28; 428/411.1

(57) ABSTRACT

An exemplary method for depositing a layer on a surface of a dielectric layer where the dielectric layer contains an organic material comprises exposing the surface of the dielectric layer to a substance, such as a substance containing nitrogen. This exposure modifies, at least, the exposed surface of the dielectric layer. The method further includes depositing a layer, such as a barrier layer, using an atomic layer deposition process on the exposed surface of the dielectric layer. In certain embodiments, exposure of the wafer to the substance containing nitrogen result in a first region of the dielectric having a first concentration of nitrogen incorporated and a second region having a second amount of nitrogen incorporated in the dielectric layer, the second concentration being higher greater than the first concentration.

### CROSS REFERENCE TO RELATED APPLICATIONS

The present application claims the benefit, under 35 U.S.C. §119(e), of U.S. Provisional Patent Application Serial No. 60/404,037, filed on Aug. 15, 2002, the entire disclosure of which is herein incorporated by reference.

### BACKGROUND INFORMATION

1. Field

The present invention relates to substrates for semiconductor processing and a method of producing such substrates.

2. Description of Related Technology

Substrates, useful for semiconductor processing, are generally produced by material deposition methods such as physical vapor deposition (PVD) and/or chemical vapor deposition (CVD). For CVD methods, the source materials may be individually fed to a reaction space concurrently where they react with each other when brought into contact with a substrate to form a film on that substrate. It is also possible to supply one source material that contains all the desired reactant species to a CVD reactor (e.g., reaction space), and heat it almost to the point where the source material would thermally decompose. In this situation, when the heated reactants contact the substrate surface, a cracking reaction occurs, and a film is grown, as is known to those working in this area. For such CVD techniques, the concentration of the different source materials (e.g., reactant species) in the reaction space determines the characteristics of the grown film.

Atomic Layer Deposition (ALD), which was previously referred to as Atomic Layer Epitaxy (ALE), is an advanced variation of CVD. The common name referring to this technique was changed from ALE into ALD to avoid possible confusion with respect to polycrystalline and amorphous thin films.

ALD methods are based on sequential self-saturated surface reactions. Such methods are described, for example, in U.S. Pat. Nos. 4,058,430 and 5,711,811. For the techniques described in those patents, the reactor design employs inert carrier and purging gases, which allow the systems to process material more rapidly than previous approaches.

In this respect, the separation of source chemicals from each other by the inert gases prevents gas-phase reactions between gaseous reactants and enables self-saturated surface reactions leading to film growth, which may be accomplished without strict temperature control of the substrates and without precise dosage control of source chemicals (e.g. reactants). Surplus chemicals and reaction byproducts are removed from the reaction chamber before the next reactive chemical is introduced into the chamber. Undesired gaseous molecules are effectively expelled from the reaction chamber by maintaining gas flow speeds above a specific rate with the use of an inert purging gas. The purging gas pushes the extra reactant and byproduct molecules towards a vacuum pump used for maintaining a suitable pressure in the reaction chamber. In this fashion, ALD methods provide for self-control of film growth.

ALD film growth processes can be divided into two segments; specifically a transient segment and a converged (linear) segment (see J. W. Lim, H. S. Park, and S. W. Kang, J. Electrochem. Soc., 148 (2001) C403). The growth mechanism during the transient segment is dependent on the nature of the substrate surface, while growth during the converged (or linear) segment is independent of the nature of the substrate surface. In this regard, the starting surface condition effects film formation and, as a consequence, ALD films obtained by employing the same number of deposition cycles and the same deposition parameters on different substrates typically have different properties/characteristics. Thus, surface preparation plays an important role in producing consistent films when using ALD techniques.

The use of plasmas to modify substrate surfaces in connection with ALD film growth is known for high dielectric constant ALD layers on oxides. For example, PCT patent application WO0243115 discloses a method of depositing a film over a surface for a partially fabricated integrated circuit. The disclosed method includes exposing the surface to the products of a plasma (such as activated chemical species), thereby modifying termination of the surface without significantly affecting the bulk properties of the substrate beneath the surface. The disclosed method further includes depositing a layer on the substrate surface after modifying the surface termination.

The use of plasmas in connection with atomic layer deposition for the area of interconnect formation has also been described. For example, A. Satta et al., in Microelectronic Engineering, 60, 2002, pages 59-69, and W. Besling et al. International Interconnect Technology Conference, June 2002, IEEE 2002 pages 288-291, disclose that chemical vapor deposited silicon oxycarbide materials treated with plasma are no longer prone to precursor diffusion into the silicon oxycarbide during ALD. It is further described that film growth on low dielectric constant (low-k) organic polymer materials using ALD approaches results in unacceptable penetration of ALD precursors inside the low-k material.

Due to the surface saturation based growth principle of ALD, this technique has been used to deposit the inner surface of porous structures such as in membranes (S. M. George, Journal of Membrane Science, 96, 259-274(1994). On the other hand, prevention of precursor penetration into porous films is a strict requirement to produce substrates useful for certain applications in semiconductor processing. In this regard, materials with low dielectric constants (low-k materials), for example, are used as interlayer dielectrics in damascene interconnect structures. Because such low-k materials are prone to precursor diffusion, there is, therefore, a need to make these low-k materials compatible with CVD techniques and, in particular, with ALD methods. Such compatibility is desirable to reduce penetration of precursors into the low-k dielectric material due to the surface saturation based growth principle. The penetration occurs as a result of the surface saturation, which provokes strong interaction of the substrate surface groups and precursor molecules. While a metallic barrier may improve such compatibility, such an approach is undesirable because deposition of a metallic barrier inside a low-k dielectric damascene structure, for example, results in an undesirable increase in the leakage current between metal lines.

To achieve compatibility of low-k thin films with ALD growth techniques, the starting surface of, for example, a substrate's surface should have adsorption sites with which the precursors can bind. If the adsorption site density is low, three-dimensional islands will be formed over the substrate surface, which is undesirable. However, if the adsorption site density is sufficiently dense, the substrate surface will be substantially covered by a two dimensional monolayer, which is a desirable outcome. Thus, a need exists for a technique to modify a substrate's polymer surface (e.g., of a low-k dielectric) prior to film growth using ALD techniques in order to create a sufficient density of adsorption sites.

### SUMMARY

An exemplary method for depositing a layer on a substrate surface having a dielectric layer that contains organic material comprises exposing an exposed surface of the dielectric layer to a substance (e.g. a gaseous substance) that contains nitrogen. As a result of this exposure, the exposed surface of the dielectric layer is modified. The method further comprises depositing the layer by an atomic layer deposition (ALD) process on the exposed surface of the dielectric layer. The organic material may be selected from the group consisting of polyarylethers, hydrogen-silsesquioxanes, methyl-silsesquioxanes polyfluorinated hydrocarbons, polyimides, fluorinated polyimides, benzocyclobutene polymers, and aromatic thermosets.

For this embodiment, by exposing the dielectric layer to the substance containing nitrogen, a first concentration (e.g., percentage of atoms) of nitrogen is incorporated into the dielectric layer in a first region. Further, a second concentration of nitrogen is incorporated into the dielectric layer in a second region. For such embodiments, the second region includes the surface exposed to the substance containing nitrogen. In certain embodiments, the concentration of nitrogen incorporated into the second dielectric region is greater than the concentration of nitrogen in the first dielectric layer region. The substance to which the dielectric layer is exposed may further comprise a compound of gases selected from the group consisting of argon, helium, oxygen and hydrogen.

For certain embodiments, the substance containing nitrogen comprises a gaseous substance and the method further comprises applying high frequency power to the substance, such that a plasma containing nitrogen is created. The gaseous substance containing nitrogen may be selected from the group consisting of N₂, ammonia, hydrogen azide, alkyl derivates of hydrogen azide, hydrazine, salts of hydrazine, alkyl derivates of hydrazine, nitrogen fluoride, hydroxyl amine, salts of hydroxylamine, primary amines, secondary amines, tertiary amines, nitrogen radicals and nitrogen in an excited state.

Depending on the particular embodiment, the layer being deposited by the ALD process may comprise a metal carbide and/or a metal nitride, where the metal is selected from the group consisting of tungsten, titanium and tantalum. Also depending on the particular embodiment, the dielectric layer may comprise a porous layer, where the pores have diameters between 0.2 nm and 15 nm.

An exemplary substrate comprises a dielectric layer containing organic material, the dielectric layer having a first region and a second region. The first region comprises a first amount of nitrogen incorporated into the dielectric layer and the second region comprises a second amount of nitrogen incorporated into the dielectric layer. For certain embodiments, the amount of nitrogen in the second region is higher than the amount of nitrogen in the first region. In the exemplary substrate, a layer is in contact with the second region of the dielectric layer, and that layer is deposited using ALD techniques.

In certain embodiments, the first and second regions of the exemplary substrate also have a compound incorporated that includes oxygen and/or hydrogen. Further, the organic material contained in the dielectric layer is selected from the group consisting of polyarylethers, hydrogen-silsesquioxanes, methyl-silsesquioxanes, polyfluorinated hydrocarbons, polyimides, fluorinated polyimides, benzocyclobutene polymers, and aromatic thermosets.

### BRIEF DESCRIPTION OF DRAWINGS

The subject matter regarded as the invention is particularly pointed out and distinctly claimed in the claims section concluding this document. The invention, however, both as to organization and method of operation, together with features and advantages thereof, may best be understood by reference to the following detailed description when read with the accompanying drawings in which:

FIG. 1 is a cross-sectional view of a substrate in accordance with an embodiment of the invention;

FIG. 2 is a graph showing the density of tungsten (W) atoms per area as a function of atomic layer deposition cycles for various substrates;

FIGS. 3a and 3b are transmission electron microscopy TEM pictures of (for FIG. 2a) a low-k dielectric substrate and (for FIG. 2b) a similar low-k dielectric substrate treated with a plasma containing nitrogen according to an embodiment of the invention, each substrate having an ALD film grown on top of the dielectric layer;

FIGS. 4a and 4b are graphs showing Rutherford Backscattering Spectrums of the tungsten peak for an ALD layer on top of (for FIG. 4a) a low-k dielectric substrate, and (for FIG. 4b) a low-k dielectric substrate treated with a nitrogen rich nitrogen/oxygen plasma according to an embodiment of the invention;

FIGS. 5a-d are graphs that show the observed optical angles Delta and Psi for various substrates with an ALD layer when exposed to toluene vapor in a closed chamber; and

FIGS. 6a-c are graphs that show the observed optical angles Delta and Psi for various substrates with an ALD layer when exposed to toluene vapor in a closed chamber.

### DETAILED DESCRIPTION

In the following detailed description, numerous specific details are set forth in order to provide a thorough understanding of the invention and how it may be practiced in particular embodiments. However, it will be understood that the present invention may be practiced without these specific details. In other instances, well-known methods, procedures and techniques have not been described in detail, so as not to obscure the present invention. While the present invention will be described with respect to particular embodiments and with reference to certain drawings, the invention is not limited thereto.

Exemplary Substrate and Exemplary Methods for Producing Such Substrates

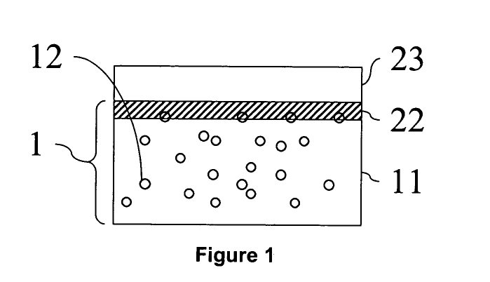

Referring now to FIG. 1, a cross-sectional view of a substrate in accordance with an embodiment of the invention is shown. The substrate shown in FIG. 1 comprises a dielectric layer 1 that includes an organic material. The dielectric layer 1 has a first region 11 and a second region 22. The first region 11 contains a first concentration of nitrogen 12 and the second region 22 has a second concentration of nitrogen 12. For the substrate shown in FIG. 1, the concentration of nitrogen 12 in the second region 22 is greater than the amount concentration of nitrogen 12 in the first region. The substrate shown in FIG. 1 further comprises a layer 23 that abuts the second region 22 of the dielectric layer 1. The layer 23 is deposited using, for example, atomic layer deposition (ALD).

The substrate shown in FIG. 1 may be produced by employing an exemplary method in accordance with an embodiment of the invention. The exemplary method includes exposing an exposed surface of the dielectric layer 1 (e.g., an exposed surface of the second region 22) to a substance, such as a gaseous substance, that contains nitrogen. This exposure to the substance modifies the exposed surface of the dielectric layer 1 (e.g., the second region 22). After this exposure, the layer 23 is deposited on the exposed surface of the second region 22, such as by ALD.

Such a method provides certain advantages for semiconductor manufacturing. For example, the method provides for improvements in the quality of layers that are deposited on dielectric layers containing organic material. As another advantage, the exemplary method provides for sealing the exposed surface (e.g., the second region 22) of the dielectric layer 1.

The exemplary methods described herein may be employed as part of semiconductor manufacturing processes and, more particularly, as part of back-end processing. In this respect, the dielectric layer 1 on which the layer 23 is deposited can be present on a substrate prior to executing such methods. The exemplary substrates described herein may be any number of substrates used in any number of semiconductor manufacturing processes. When employing such methods, the substrates may comprise partially processed semiconductor wafers or, alternatively, may comprise unprocessed wafers (which may be termed pristine wafers). Alternatively, the substrate may comprise a slice of semiconductor material (e.g. Si, GaAs, Ge) or insulating material (e.g., a glass slice), or a conductive material. In certain embodiments, the substrate may comprise a patterned conductive layer. For example, when the substrate comprises a partially processed wafer or slice of material, at least part of an active and/or passive device may already be formed and/or at least a part of the structures interconnecting these devices may be already formed.

In this context, the term “layer” should be understood to mean any layer having a thickness of at least one molecule. For example, a layer may comprise, but is not limited to, a monolayer, a stack of monolayers, a film with a thickness less than 50 nm, or a film with a thickness greater than 50 mn.

In an exemplary embodiment, the dielectric layer 1 comprises organic material. In this context, organic material refers to polymeric material or oligomeric material. Such materials contain organic side groups, or contain carbon-carbon bonds in the polymer or oligomer backbone. For example, such compounds include polyarylethers, hydrogen-silsesquioxanes, methyl-silsesquioxanes, polymethylsiloxanes, polyphenylsiloxanes, polyfluorinated hydrocarbons, polyimides, fluorinated polyimides, benzocyclobutene polymers, or aromatic thermosets. In embodiments that employ aromatic thermosets, one particular type of thermoset that may be used is low-k dielectric resins. One such resin is available from Dow Chemical Company under the registered trademark SiLK®. Using such resinous low-k dielectric materials, the organic material in the dielectric layer is obtained by spin coating the substrate using an organic polymer/oligomer solution and then by solvent removal, as is known by those working in this area.

In embodiments employing polymeric materials, the organic polymer is preferably, but not necessarily, cross linked. Cross linking may be achieved by keeping the polymeric material (e.g., after application to the substrate) at an elevated temperature for a period of time. Such cross linking may be carried out in a furnace, on a hot plate, or by using any appropriate heating device. Curing temperatures for cross linking organic polymers may be between 200° C. and 500° C., or in certain embodiments, between 300° C. and 400° C. Such elevated temperature treatment may be done before or, alternatively, after the layer 23 is deposited (e.g., using ALD).

In certain embodiments, the cross linked organic polymer contains pores. Such pores may be created by using porogens, high boiling temperature solvents (as described in e.g., Semiconductor International, May 2001, pages 79-85), among other possible techniques.

Depending on the particular embodiment, the size of the pores may be below 20 nm, below 10 nm, below 5 nm, or below 2 nm. Similarly, the porosity (e.g. density of pores), depending on the embodiment, may be less than or equal to 90 percent by volume, less than or equal to 70 percent by volume, less than or equal to 50 percent by volume, or less than or equal to 40 percent by volume.

In an exemplary method, as was noted above, the substance to which the exposed layer of the dielectric layer 1 is exposed contains nitrogen. Depending on the particular embodiment, this nitrogen may be provided from N₂, ammonia (NH₃); hydrogen azide (HN₃) and the alkyl derivates of HN_{3,} such as CH₃N₃; hydrazine (N₂H₄) and salts of hydrazine, such as hydrazine hydrochloride; alkyl derivates of hydrazine such as dimethyl hydrazine; nitrogen fluoride NF3; hydroxyl amine (NH2OH) and its salts, such as hydroxylamine hydrochloride; primary, secondary and tertiary amines such as methylamine, diethylamine and triethylamine, and nitrogen radicals such as NH2., NH.. and N... wherein “.” means a free electron capable of bonding, and excited states of nitrogen (N₂*).

Further, in certain embodiments, subjecting the wafer to a substance containing nitrogen comprises applying a high frequency power to a gaseous substance that includes at least one compound containing nitrogen (e.g. nitrogen gas and/or ammonia), such that a plasma containing nitrogen is created. For such embodiments, the plasma is generated by subjecting the gaseous substance to a radio frequency (RF) power. The RF power may be applied in a chamber, such as a closed reaction chamber, in which only a top power is applied. Alternatively, both a top power and a bottom power (also called a bias) may be applied in the chamber. For such embodiments, the top power used to generate the plasma may be between 10 watt (W) and 3000 W, between 300 and 3000 W, between 100 W and 2000 W, or between 100 W and 1000 W. For embodiments that employ a bias, the bottom power used to generate the plasma may be between 1 W and 2000 W, between 10 and 1000 W, or between 50 W and 800 W. When applying both a top power and bias, the top power used may be between 1 W and 1000 W and the bias applied may be between 1 W and 2000, for example.

It is noted that for embodiments where plasma is employed using only a top power, the plasma may be generated in one chamber and the substrate may be exposed to that plasma in a separate chamber. Alternatively, such as in embodiments employing both a top power and a bias, the substrate (after application of the organic polymer) is exposed to the plasma in the same chamber where the plasma is generated.

During exposure of the organic polymer material (e.g., the dielectric layer 1) to the substance containing nitrogen, the temperature of the chamber, depending on the embodiment may be between −50° C. and 400° C., between 0° C. and 250° C., or between 10° C. and 30° C. Further, the pressure of the chamber during exposure of the substrate may be between 1 mTorr and 10 Torr, between 3 mTorr and 5 Torr, or between 5 mTorr and 1 Torr.

As was previously discussed, in certain embodiments, the substance to which the exposed surface (of the second region 22) of the dielectric layer 1 is exposed may be a gaseous substance that contains nitrogen, such as in the forms described above. For such embodiments, the gaseous substance may further comprise a compound selected from the group consisting of argon, helium, oxygen and hydrogen such that a gaseous mixture is formed. The weight ratio of the molecules containing nitrogen atoms (e.g., N₂ or e.g. NH₃) to other compounds (or molecules) in the gaseous mixture may be greater than or equal to 1%, greater than or equal 5%, greater than or equal 10%, greater than or equal to 40%, or greater than or equal to 80%. Further with regard to the concentration of nitrogen in such gaseous mixtures, the gaseous mixture may contain the gases N₂ and H₂ in a volume ratio between 99 to 1 and 1 to 99, in a volume ratio between 9 to 1 and 1 to 9, or in a volume ratio between 5 to 1 and 1 to 5. Alternatively, the gaseous mixture may contain the gases N₂ and O_{2,} or the gases NH₃ and O₂ in the same volume ratios as were noted for N₂ and H₂ above.

Exposure of an exposed surface of the dielectric layer 1 to such substances (e.g., gaseous substances, gaseous mixtures and/or plasmas) results in a first region 11 of the dielectric layer 1 having a first amount of nitrogen incorporated, and a second region 22 of the dielectric layer 1 having a second amount of nitrogen incorporated. For such embodiments, the second regions 22 includes the surface that is exposed to the substance, as described above. For certain embodiments, the concentration of nitrogen in the second region 22 is higher than the concentration of nitrogen in the first region 11 of the dielectric layer 1. In this regard, chemical groups that contain nitrogen are formed on the exposed surface of the dielectric layer. The composition of these chemical groups depends, at least in part, on the composition of the dielectric layer and the composition of the plasma or substance applied. The formation of these chemical groups enhances the quality of films grown using deposition techniques such as ALD, as these nitrogen containing groups act as precursor binding sites, thus prohibiting migration of conductive material (e.g., such as copper) into the dielectric layer.

Referring to FIG. 1, in an exemplary embodiment, a layer 23 is deposited on the exposed surface of the second region 22 of the dielectric layer 1 by an ALD process. The ALD process may be thermally activated or, alternatively, may be radical enhanced. Depending on the particular substrate and the composition of the layer 23, the deposition temperature for embodiments using thermally activated ALD may be between 200° C. and 700° C., between 250° C. and 500° C., or between 275° C. and 350° C. For radical enhanced ALD, the deposition temperature may be between 0° C. and 400° C., between 20° C. and 300° C., or between 100° C. and 200° C.

For the exemplary method, the deposited layer 23 may be a metal carbide and/or metal nitride, for example. Such layers are described in PCT Patent Applications WO0129280A1 and WO0127347. The metal of such metal carbides and/or metal nitrides may comprise one or more of the elements tungsten, titanium, tantalum, zirconium, hafnium, vanadium, niobium, chromium and molybdenum. In the exemplary method, the metal carbide or metal nitride layer is generated from one or more source materials. In this regard, suitable metal source materials include halides, fluorides, chlorides, bromides, iodides, or metal organic compounds, such as alkylaminos, cyclopentadienyls, dithiocarbamates or betadiketonates of a desired metal. The carbide source material may be selected from among various hydrocarbons and alkyl boranes, wherein the alkyl is linear or branched C1 to C4, o-alkyl, such as C1-C4 alkyls. In certain embodiments, the alkyl used is triethyl boron.

The exemplary methods disclosed herein are particularly useful in the area of damascene processing, such as for the deposition of a metal barrier layer in an opening being formed in the dielectric layer (such as the dielectric layer 1 of FIG. 1). In this context, the term “dielectric layer” refers to a layer or a stack of layers made of substantially non-conductive material, which is used to electrically isolate layers made of conductive material from each other, such as in a semiconductor device. In an exemplary embodiment, the deposited layer 23 (e.g., deposited using ALD) is a layer or, alternatively, a stack of layers, that prevents the diffusion of conductive material (which is used to fill the opening in the dielectric layer for a damascene process) into the insulating layer. The composition of the barrier layer is determined, at least in part, by the conductive material used to fill the opening in the dielectric layer 1. For example when the conductive material comprises copper, the barrier layer may include, but is not limited to, Ti, TiN, Ta, TaN, TaₓSi_{y}N_{z}, WₓN_{y}, WₓC_{y}N_{z}, SiC, SiOC, hydrogenated SiC, hydrogenated SiOC, and combinations thereof.

In another exemplary method, the deposited layer 23 may take the form of a copper barrier layer, which is deposited in an opening that is formed in the dielectric layer 1 on a substrate, such as the substrate shown in FIG. 1. The dielectric layer 1 comprises organic material and is deposited on the substrate, such as by using a dielectric resin, as was previously described. The substrate may be a partially processed wafer or, alternatively, an unprocessed (e.g., pristine) wafer. The dielectric layer 1 may be deposited on a previously applied metal layer, a contact level layer, or a transistor level layer.

The dielectric layer 1 is then patterned, such as by using photolithography techniques. During a dry etching operation of the photolithography process, an opening is formed in the dielectric layer. The opening in the dielectric layer may be an opening that will be employed to implement a dual damascene approach. The etching plasma (e.g. for the dry etch) comprises a substance containing nitrogen (e.g., such as a gaseous substance). As a result of the dry etch, the dual damascene opening is created and the exposed surface of the dielectric layer is chemically modified, meaning that nitrogen containing groups are formed on the exposed surface, as has been previously described. Subsequently, a barrier layer 23 is deposited using ALD techniques, based on the exchange of chemical groups, which is known to those working in this area. In this regard, the substrate is brought in contact with a precursor (or series of precursors) such that the barrier layer is deposited. Once the barrier layer is deposited, the opening in the dielectric layer 1 is filled, such as with copper, as was previously discussed.

Empirical Samples

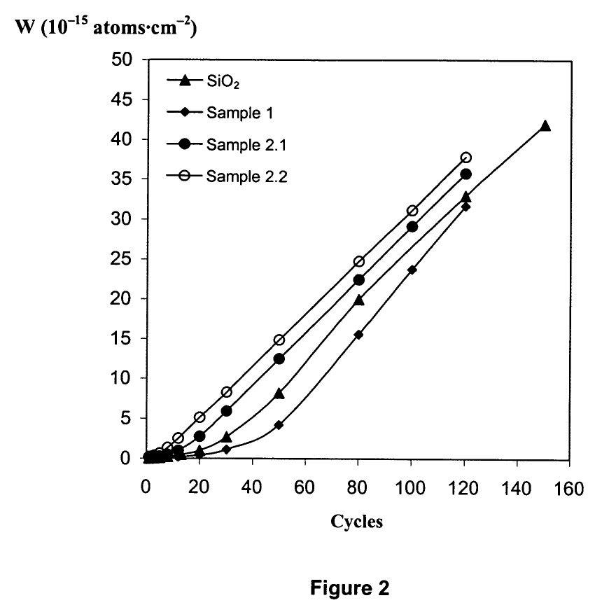

A description of various substrates that were empirically studied to demonstrate the advantages of the exemplary embodiments described herein are set forth below. Each of the various substrates that were studied is referred to as a “Sample.” In this respect, Sample 1 is an untreated substrate while Samples 2.1-2.6 are exemplary substrates, which are treated in accordance with embodiments of the invention. It will be appreciated that these descriptions are provided by way of example and are not limiting in scope to the invention. The “Samples” are compared and discussed below with reference to FIGS. 2-6.

Dielectric Deposition

Sample 1

Dielectric deposition was performed on 200 mm silicon wafers. The wafers were cleaned with a mixture containing 1 part NH₃ (30 wt. %), 1 part H₂O₂ (30 wt. %), and 5 parts deionize H₂O. A triamino-methyl-silane adhesion promoter, AP4000, was then applied. A dielectric resin (such as SiLK-I-360, available from Dow Chemical) was spin coated onto the wafers. The wafers were then baked at 325° C. for 60 seconds. The wafers were then cured for 30 min at 400° C. in a horizontal furnace under an N₂ ambient in order to prevent oxidation of the dielectric film. Cross linking of the polymer was achieved in this cure operation. The wafers were loaded into and unloaded from the furnace at 200° C. Further, the wafers were kept inside the furnace under N₂ ambient during temperature ramp up/down of the furnace. Such substrates may be referred to as pristine dielectric substrates.

Dielectric Film Layer Surface Plasma Treatments

For each of the following “Samples”, pristine dielectric substrates were obtained by the process described above for Sample 1. After the treatment described above was applied, the pristine substrates (Samples1) were kept in clean room atmosphere for a period of several days before further processing according to the individual methods described for each “Sample.” The pristine substrates (untreated with, for example, a plasma) used in this evaluation were also kept in the clean room environment.

Sample 2.1

For this sample, a treatment of the cross-linked polymer film of the pristine substrates was performed in a resist strip chamber for 4 seconds at 230 degree Celsius at 0.5 Torr with a substance (e.g., gaseous substance) composed of 1 part nitrogen by volume and 20 parts oxygen by volume. This treatment may be termed an oxygen rich plasma or ICP treatment). For this treatment, an RF power (top power) of 900 W was applied.

Sample 2.2

For this sample, a treatment of the cross-linked polymer film of the pristine substrates was performed in a high-density plasma tool for 4 seconds at 20 degree Celsius at 7 mTorr with a substance composed of 5 parts nitrogen by volume and 1 part oxygen by volume, which may be termed a nitrogen rich plasma or RIP plasma. For this treatment, an RF top power of 1700 W was applied. Further a bias (bottom power) of 600 W was applied.

Sample 2.3

For this sample, a treatment of the cross-linked polymer film of the pristine substrates was performed in a high-density plasma tool for 5 seconds at 20 degree Celsius at 7 mTorr with a substance composed of 5 parts nitrogen by volume and 1 part oxygen by volume, which may be termed nitrogen rich plasma or RIP plasma. For this treatment, an RF top power of 1700 W was applied. Further a bias (bottom power) of 600 W was applied.

Sample 2.4

For this sample, a treatment of the cross-linked polymer film of the pristine substrates was performed in a high-density plasma tool for 5 seconds at 20 degree Celsius at 7 mTorr with a substance composed of nitrogen. For this treatment, an RF top power of 1200 W was applied. Further a bias (bottom power) of 600 W was applied.

Sample 2.5

For this sample, a treatment of the cross-linked polymer film of the pristine substrates was performed in a high-density plasma tool for 5 seconds at 20 degree Celsius at 7 mTorr with a substance composed of argon. For this treatment, an RF top power of 1200 W was applied. Further a bias (bottom power) of 600 W was applied.

Sample 2.6

For this sample, a treatment of the cross-linked polymer film of the pristine substrates was performed in a high-density plasma tool for 5 seconds at 20 degree Celsius at 7 mTorr with a substance composed of ammonia. For this treatment, an RF top power of 1200 W was applied. Further a bias (bottom power) of 600 W was applied.

After the treatments described above were applied, the substrates (of Samples 2.1-2.6) were kept in clean room atmosphere for a period of several days before ALD deposition was performed on the samples.

Atomic Layer Deposition

An automated reactor was used for deposition of a tungsten based barrier material (e.g., the layer 23 of FIG. 1). This deposition was achieved using ALD according to an A, B, C, A, B . . . pulse sequence, where individual As, Bs, and Cs stand for the precursors triethylborane ((C₂H₅)₃B, Sigma-Aldrich), tungsten hexaflouride (WF₆), and ammonia (NH_{3,} Messer-Griesheim), respectively, while the series ‘A, B, C’ represents a single deposition cycle producing WCₓN_{y} (x=0.7 and y=0.3). The precursors were fed into the reactor through needle and solenoid valves. WF₆ and NH₃ were applied as pure compounds, while (C₂H₅)₃B was evaporated and dosed by mixing the liquid precursor with a nitrogen carrier gas flow at 20° C. Excess precursor gas was removed by flowing nitrogen (N₂) for two seconds after each precursor pulse. Residual moisture in the system was reduced below a level of 1 ppb by using gas purifiers (Millipore, Mykrolis GmbH) for N₂ and NH_{3,} respectively. The temperature during the deposition was approximately 350° C., and the maximum pressure during deposition was approximately 2 hPa. For each of the substrate types, the Samples were produced by applying a number of deposition cycles ranging from 1 to 120.

Ellipsometric Measurements

The barrier film optical properties and thickness were measured by spectroscopic ellipsometer (SE) in the range of 350-870 nm. The measurement results were fitted to a Cauchy model. The refractive index (n) and the extinction coefficient (k) of WCₓN_{y} were determined once for the thickest film, at 632.8 nm wavelength n_{WCxNy}=2.99 and k_{WCxNy}=1.57. Then the optical constants of the WCₓN_{y} film were fixed to reduce the number of variables to be fitted in the Cauchy model. The same procedure was applied to the organic polymer (dielectric) layer optical constants, which were also fixed, such that only thickness was fitted (approximated by two Cauchy layers).

Barrier integrity was measured by ellipsometric porosimetry. This technique is usually utilized to evaluate the structure of porous films. During such measurements, the substrate is placed in a vacuum chamber that is filled with toluene vapor. Adsorption of toluene by a porous film on the substrate causes a change in its optical properties. Such changes are observed using in-situ ellipsometric measurements (such as of the angles Delta and Psi). If a porous film is sealed by a high integrity barrier layer, it inhibits the toluene from migrating into the film and, therefore, small changes are observed in the optical properties of the film. This provides a metric of the sealing integrity of a porous film barrier layer.

Other Measurements

The sheet resistance of the deposited WCₓN_{y} barrier layer on pristine dielectric substrate, and exemplary treated substrates (such as Samples 2.1-2.6) was measured by a four-point probe. A control wafer of thermal oxide was also processed and measured for comparison.

X-ray photoelectron spectrometry (XPS) measurements were performed with an angle between the sample and the analyzer of 45 degrees resulting in an information depth of 5 nm. The analysis was done at a depth of 5 nm and quantification of data was done using standard Wagner sensitivity factors. Under this condition, the total error for quantification is assumed to be approximately 10%. Further, Rutherford back scattering spectroscopy (RBS) measurements of the 1-120 cycles ALD barrier films were also performed.

Table 1 illustrates that an increased amount of nitrogen concentration was observed for the exemplary substrates that were treated with a nitrogen plasma by comparing the elemental composition of the top 10 nm of the layer before and after plasma exposure. The values relate to Samples 1 and 2.1-2.6 as obtained according to the above described methods.

TABLE 1
Elemental analysis as determined by X-ray photoelectron
spectrometry of organic polymer surface (10 nm)
XPS chemical before and
after plasma treatment

| Sample | C | N | O |
|---|---|---|---|
| Sample 1 | 98.1 | <0.1 | 1.9 |
| Sample 2.1 | 76.1 | 1.5 | 22.4 |
| Sample 2.2 | 64.9 | 12.5 | 22.4 |
| Sample 2.3 | 69.9 | 9.2 | 21.0 |
| Sample 2.4 | 61.5 | 22.7 | 15.8 |
| Sample 2.5 | 83.7 | 0.8 | 15.5 |
| Sample 2.6 | 69.4 | 13.3 | 17.3 |

Comparison of ALD growth on different substrates is made in FIG. 2, which shows the area density of tungsten atoms in dependence on number of deposition cycles. The density was determined by RBS on substrates obtained according to the above descriptions. For reference, a film grown on a silicon dioxide substrate was also evaluated. It may be seen in FIG. 2 that growth on the nitrogen rich nitrogen/oxygen plasma treated sample (Sample 2.2) occurs with a very short transient period, indicating two-dimensional growth is occurring. Growth on the pristine substrates (Sample 1) takes place with an extended transient period, indicating that mainly undesirable island type, three-dimensional growth is occurring. Growth on the oxygen rich nitrogen/oxygen plasma treated polymer surface (Sample 2.1) shows a faster transition to linear ALD typical behavior than Sample 1. When comparing the substrates represented by the traces shown in FIG. 2 to the growth on SiO₂, it may be seen that the treatments for the exemplary substrates and methods are effective in enhancing ALD growth on organic polymer dielectric surfaces. In this regard, the slope of the curve for Sample 1 (the pristine substrate) is greater than on those that were plasma treated. This indicates that the linear part of the ALD growth for Sample 1 has not been reached at one hundred cycles. Due to the three dimensional shape of growing ALD islands, the total surface available for precursor adsorption during ALD increases first during island formation and then decreases during coalescence of the islands. Therefore, the growth curves with pronounced three dimensional growth have an S-type shape (such as for the SiO2 reference substrate). Hence, the exemplary substrates provide a desirable advantage of enabling very thin but nevertheless continuous ALD films to be grown on top of organic polymer (e.g., dielectric) materials.

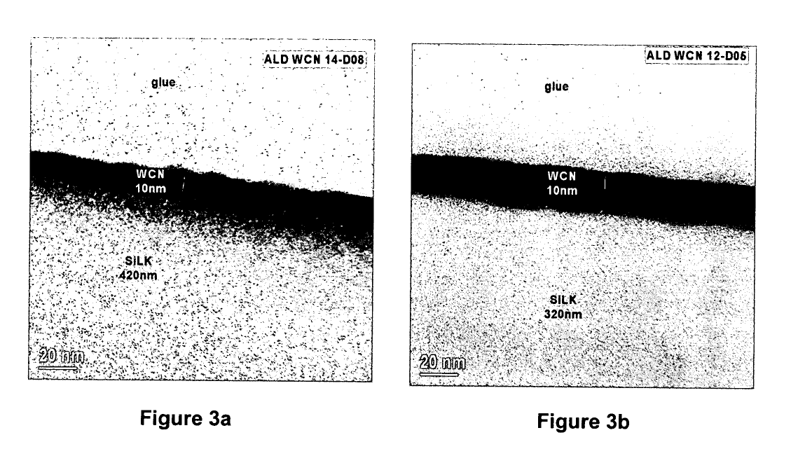

FIGS. 3a and 3b are two transmission electron microscope pictures. FIG. 3a illustrates the formation of islands in the ALD deposited layer on an organic polymer substrate (such as on Sample 1). FIG. 3b illustrates a continuous ALD film as deposited on a substrate treated with nitrogen rich nitrogen/oxygen plasma (e.g., Sample 2.2). Further it can be seen from FIG. 3b, that the exemplary treated substrate has a sharp interface between organic polymer material and the ALD film. In contrast, FIG. 3a shows dark dots in the polymer layer, which indicates penetration of precursors and consequent intrusion of material (e.g., conductive material) into the bulk of the polymer layer, which is undesirable.

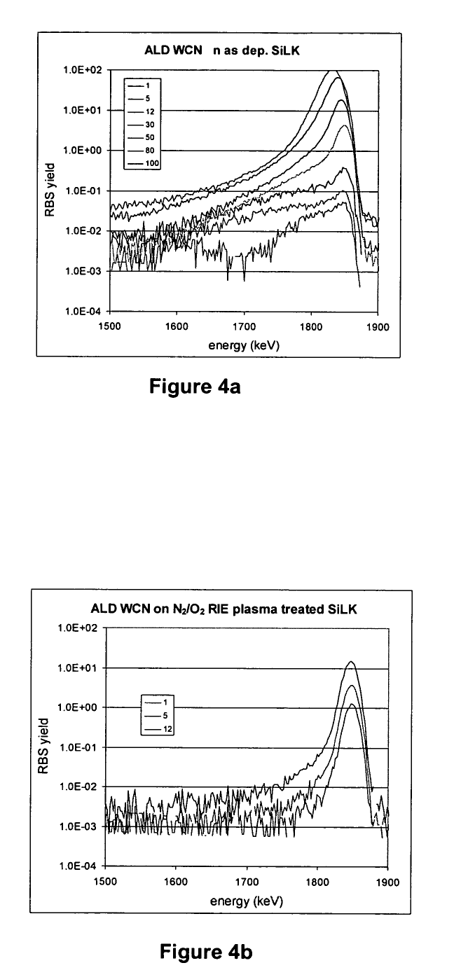

FIGS. 4a and 4b are two graphs that further illustrate the advantage of such exemplary substrates. FIG. 4a shows RBS tungsten peaks for a substrate with an ALD film that is deposited on an organic polymer substrate that has not been exposed to nitrogen plasma before ALD deposition (such as Sample 1). The tungsten peak distribution, as may be seen in FIG. 4a, has an extended tail. This asymmetry indicates the undesirable diffusion of tungsten into the organic polymer (dielectric) layer. In contrast, FIG. 4b shows RBS tungsten peaks of a substrate where a treatment of the wafer with a nitrogen plasma is done (such as for samples 2.3 and 2.3). For this substrate, the tungsten peaks are almost symmetrically distributed around the center.

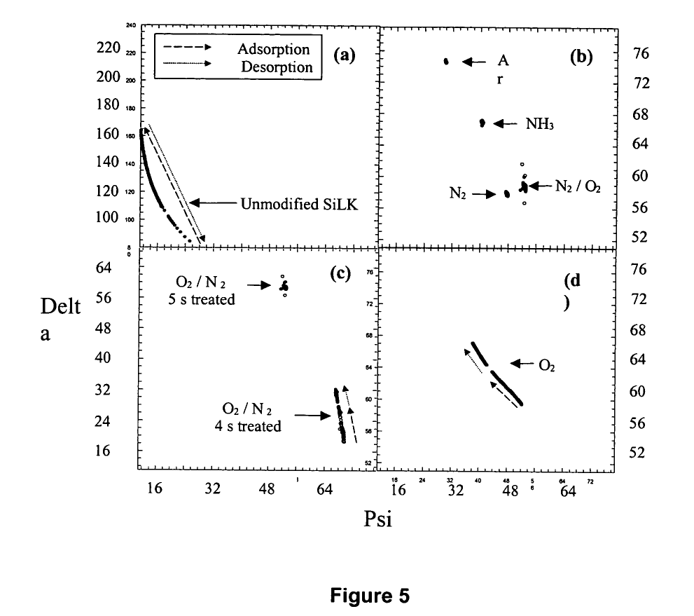

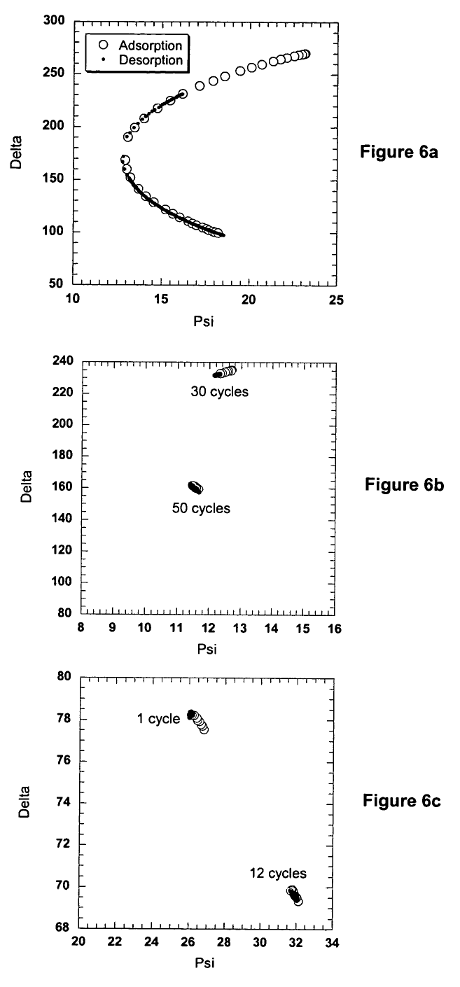

FIGS. 5 and 6 further illustrate that, in such exemplary methods, very thin but nevertheless continuous ALD films may be grown on top of organic polymer materials. In this respect, FIGS. 5 and 6 shows the permeability to toluene vapor of substrates generated using exemplary methods described herein. In this regard, toluene vapor can penetrate through imperfections in a film and be absorbed by an underlying polymer material (e.g., the dielectric layer 1) causing changes in optical properties. Changes in optical properties, namely in the observed ellipsometric angles Delta and Psi, of the polymer or polymer-ALD film system were monitored while the substrate was exposed to toluene vapor in a closed chamber. Systems to perform these kind of measurements are commercially available, e.g. from XPEQT, Switzerland.

In FIGS. 5 and 6, absorption (or adsorption) is indicated by large open circles, while desorption is indicated by small filled circles. FIG. 5a is a graph that illustrates the change in the ellipsometric angles Delta and Psi for the “untreated” sample described as Sample 1 above when exposed to toluene vapor in a chamber. The change in the ellipsometric angles Delta and Psi indicates adsorption of toluene into the sample. This change was observed to be reversible due to desorption of the toluene through the ALD deposited layer, indicating the presence of large pores in the layer 23.

FIG. 5b is a graph that illustrates the change in the ellipsometric angles Delta and Psi for one of the N₂/O₂ treated sample, the nitrogen treated sample, the Argon treated sample and the ammonia sample according to, respectively, Samples 2.3, 2.4, 2.5, and 2.6. The observed ellipsometric angles Delta and Psi for these samples during toluene exposure do not significantly change, which indicates that the dielectric layers are sealed, such that toluene is not able to penetrate them.

FIG. 5c is a graph that that illustrates the change in the ellipsometric angles Delta and Psi only for the O₂/N₂ treated Samples 2.2 and 2.3. The ellipsometric angles Delta and Psi change slightly for the material that received a 4 second treatment (Sample 2.2), indicating some adsorption of toluene into the sample. This change, however, was observed not to be reversible, which indicates that the deposited layer (e.g. the layer 23 in FIG. 1) in combination with the dielectric layer (e.g. the dielectric layer 11 in FIG. 1) was not sufficiently porous to allow desorption of toluene. The lack of desorption further indicates that the sealing integrity of the Sample 2.2 was improved over the Sample 1. As may also be see in FIG. 5c, Delta and Psi do not substantially change when the treatment is done for 5 seconds, as is shown for the Sample 2.3, which indicates substantially improved sealing integrity as compared to Sample 1.

FIG. 5d is a graph that illustrates the change in the ellipsometric angles Delta and Psi for the O₂ treated sample according to Sample 2.1. From FIG. 5d, it may be seen that the ellipsometric angles Delta and Psi display some amount of change, indicating adsorption of toluene during exposure of the substrate. However, as with Sample 2.2, this absorption was not observed to be reversible, indicating a lack of large pores in the deposited layer and dielectric layer of the sample.

It is noted that the same experiment was performed using Samples 1, 2.1, 2.2, 2.3, 2.4, 2.5 and 2.6, with the Samples 2.1-2.6 showing an improved behavior of the dielectric layer as compared to Sample 1. For those samples where the ellipsometric angles Delta and Psi change, indicating adsorption of toluene into the sample, this change was not observed to be reversible, which indicates that that the pores are small as compared to those of Sample 1. For the samples where no significant change was observed in Delta and Psi, this lack of absorption indicates an even higher sealing integrity for these samples and that smaller pores exist in the exposed layer (e.g. the deposited layer 23) of the substrate as compared to Sample 1.

Referring now to FIG. 6, FIG. 6a is a higher resolution graph that corresponds with FIG. 5a and illustrates the change in Delta and Psi for a sample with a 120 cycle ALD film on top of an untreated dielectric surface (e.g., Sample 1). FIG. 6b is a higher resolution graph that shows two curves (for samples with 30 and 50 cycle ALD films), which corresponds to the oxygen rich nitrogen/oxygen plasma treated sample 2.1 shown in FIG. 5d. FIG. 6c is another higher magnitude graph that shows two curves (for samples with 1 and 12 cycle ALD films) that correspond to the nitrogen rich nitrogen/oxygen plasma treated sample 2.2.

The observed differences in Delta and Psi shown in FIGS. 6a-c from those shown in FIG. 5 are due to the integrity of the ALD films being observed. From FIG. 6, it can be concluded that the ALD film obtained with 120 deposition cycles on a pristine substrate is extremely permeable to toluene vapor, while the ALD films obtained with the other conditions (Samples 2.1 and 2.2) have substantially improved sealing integrity. It may also be seen in FIG. 6 that one of the highest sealing integrities for the samples studies occurred for the sample with a 50 deposition cycle ALD film deposited on a substrate exposed to an oxygen rich nitrogen/oxygen plasma (such as described for Sample 2.1). Such a film is shown to be substantially impermeable to toluene vapor. However, it may also be seen that the ALD film obtained with 12 deposition cycles on a substrate exposed to a nitrogen rich plasma treated (such as described for sample 2.2), is also substantially impermeable to toluene vapor.

A further advantage of the exemplary embodiments is the homogeneity of the ALD films produced. For example, samples obtained using the methods described for samples 2.1-2.6 on 200 mm silicon wafers were characterized for sheet resistance. The within wafer non uniformity (WIWNU) of sheet resistance measured with a four point probe (polar forty nine point map with 5 mm edge exclusion) for a 120 cycle WCN ALD film on an untreated substrate had a 1 sigma variation of 25%. In comparison, a 120 cycle WCN ALD film deposited in the same manner on a substrate treated with nitrogen rich nitrogen/oxygen plasma produced a substrate with a WIWNU of 33% in terms of the 1 sigma standard deviation, which is a desirable improvement in homogeneity.

It is to be understood that although preferred embodiments, specific constructions and configurations, as well as materials, have been discussed herein for devices according to embodiments of the invention, various changes or modifications in form and detail may be made without departing from the scope and spirit of this invention as defined by the appended claims.

What is claimed is:

1. A method for depositing a layer on a surface of a dielectric layer, the dielectric layer containing an organic material, the method comprising:
exposing the surface of the dielectric layer to a gaseous substance that contains nitrogen, thereby modifying at least the exposed surface of the dielectric layer; and
depositing a layer by an atomic layer deposition (ALD) process on the exposed surface of the dielectric layer.

2. The method of claim 1, wherein the exposing the surface of the dielectric layer results in a first region of the dielectric layer having a first concentration of nitrogen incorporated therein and a second region of the dielectric layer having a second concentration of nitrogen incorporated therein,
wherein the concentration of nitrogen incorporated in the second region of the dielectric layer is greater than the concentration of nitrogen incorporated in the first region of the dielectric layer; and
the second region includes the surface that is exposed to the substance.

3. The method of claim 1, wherein the gaseous substance further comprises a compound selected from the group consisting of argon, helium, oxygen and hydrogen.

4. The method of claim 1, wherein exposing the surface to a gaseous substance containing nitrogen further comprises applying an RF power such that a plasma containing nitrogen is created.

5. The method of claim 1, wherein the gaseous substance is selected from the group consisting of N₂, ammonia, hydrogen azide, alkyl derivates of hydrogen azide, hydrazine, salts of hydrazine, alkyl derivates of hydrazine, nitrogen fluoride, hydroxyl amine, salts of hydroxylamine, primary amines, secondary amines, tertiary amines, nitrogen radicals and nitrogen in the excited state.

6. The method of claim 1, wherein the organic material is selected from the group consisting of polyarylethers, hydrogen-silsesquioxanes, methyl-silsesquioxanes, polyfluorinated hydrocarbons, polyimides, fluorinated polyimides, benzocyclobutene polymers, and aromatic thermosets.

7. The method of claim 1, wherein the layer deposited by the ALD process comprises at least one of a metal carbide and a metal nitride.

8. The method of claim 7, wherein the metal of at least one of the metal carbide and the metal nitride is selected from the group consisting of tungsten, titanium and tantalum.

9. The method of claim 1, wherein the dielectric layer contains pores.

10. The method as recited in claim 9, wherein the pores have diameters between 0.2 nm and 15 nm.

11. A substrate comprising:
a dielectric layer comprising an organic material, the dielectric layer having a first region and a second region, the first region having a first concentration of nitrogen incorporated therein and the second region having a second concentration of nitrogen incorporated therein,
wherein the concentration of nitrogen in the second region is greater than the concentration of nitrogen in the first region; and
a layer, the layer being in contact with the second region of the dielectric layer, the layer being deposited by atomic layer deposition (ALD.

12. The substrate of claim 11, wherein the first region and the second region further have a compound incorporated therein, wherein the compound is selected from the group consisting of argon, helium, oxygen and hydrogen.

13. The substrate of claim 11, wherein the organic material is selected from the group consisting of polyarylethers, hydrogen-silsesquioxanes, methyl-silsesquioxanes, polyfluorinated hydrocarbons, polyimides, fluorinated polyimides, benzocyclobutene polymers, and aromatic thermosets.

14. The substrate of claim 11, wherein the layer comprises at least one of a metal carbide and a metal nitride

15. The substrate of claim 14, wherein the metal of at least one of the metal carbide and the metal nitride is selected from the group consisting of tungsten, titanium and tantalum.

16. The substrate of claim 15, wherein the dielectric layer contains pores.

17. The substrate of claim 16, wherein the pores have diameters between 0.2 nm and 15 nm.
